(19) United States
(12) Patent Application Publication
(10) Pub. No.: US 2008/0309191 A1
(43) Pub. Date: Dec. 18, 2008

(54) Mems moving platform with lateral zipping actuators

(76) Inventors: Tsung-Kuan Allen Chou, San Jose, CA (US); Oing Ma, San Jose, CA (US)

Correspondence Address: SETH KALSON;c/o INTELLEVATE, LLC, P.O. BOX 52050, MINNEAPOLIS, MN, 55402, US

(21) Appl. No.: 11/818,315

(22) Filed: Jun. 14, 2007

(51) Int. Cl. H02N 1/00; B81B 7/02

(52) U.S. Cl. 310/309

(57) ABSTRACT

A MEMS platform with four actuators and four corresponding actuation electrodes. Movement of the platform in the x-y lateral plane is controlled by voltages applied to the four actuation electrodes. Other embodiments are described and claimed.

### FIELD

The present invention relates to MEMS (Micro-Electro-Mechanical Systems) technology.

### BACKGROUND

FIG. 1 illustrates a top plan view of the mover stage in a MEMS (Micro-Electro-Mechanical System) seek-scan-probe memory device. The mover carries scanning probes (not shown), which are in contact with a storage media (not shown) to perform reads, writes, and erases. To provide this functionality, the probes need to move in both the x and y directions to scan through certain areas for a data search or read. This scanning step is carried out by the mover. By applying various voltages to the comb electrodes, the mover may be moved in a lateral direction (parallel to the plane of the drawing.) For simplicity, only two sets of comb electrodes are illustrated in FIG. 1, which provide movement in the y direction, but in practice additional sets of comb electrodes are used to provide movement in both the x and y directions.

Moving the mover by sets of comb electrodes is sensitive to gap consistency between the electrodes. Vibration may cause a change in the gap, resulting in actuation error. Furthermore, comb electrodes provide a relatively low electrostatic force, which usually limits the mover the small displacements.

### BRIEF DESCRIPTION OF THE DRAWINGS

FIG. 1 illustrates a prior art MEMS moving platform.

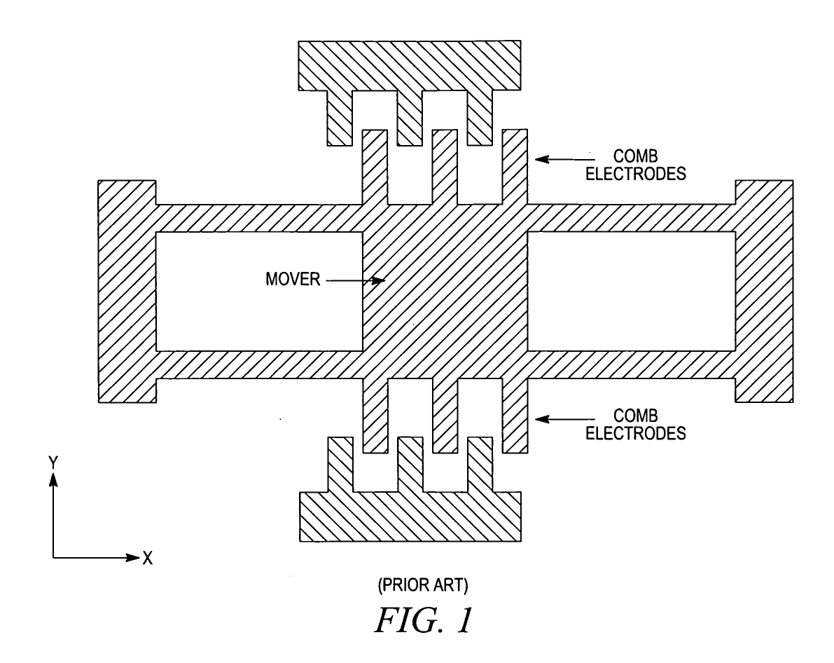

FIG. 2 illustrates a MEMS moving platform according to an embodiment of the present invention.

FIG. 3 illustrates a MEMS moving platform according to another embodiment of the present invention.

FIG. 4 illustrates an actuation electrode and actuator according to an embodiment of the present invention.

### DESCRIPTION OF EMBODIMENTS

In the description that follows, the scope of the term “some embodiments” is not to be so limited as to mean more than one embodiment, but rather, the scope may include one embodiment, more than one embodiment, or perhaps all embodiments.

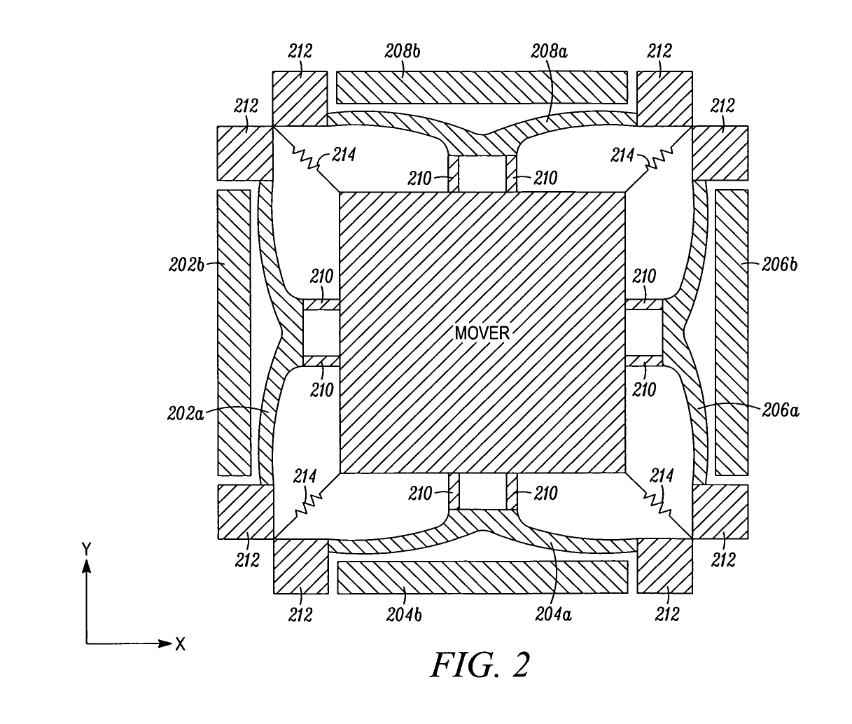

FIG. 2 illustrates a top plan view of a mover, labeled as such, tethered to four actuators labeled 202a, 204a, 206a, and 208a. Associated with these four actuators are, respectively, four actuation electrodes 202b, 204b, 206b, and 208b. The scanning probes, although not shown, are coupled to the mover and, relative to the plan view indicated by FIG. 2, would be underneath the mover. Tethering beams, labeled 210, couple the mover to the actuators and suspend the mover in air. The actuators are coupled to anchors 212, and anchors 212 are coupled to a CMOS (Complementary Metal Oxide Semiconductor) substrate (not shown). Electrodes 202b, 204b, 206b, and 208b are anchored to the CMOS substrate. The mover may be electrically grounded through the anchor by way of tether beams 214. Additional tethering beams, such as those labeled as 214, may be used. When tethering beams 214 are used, electrodes 202a, 204a, 206a, and 208a may not need to couple to anchor 212. A dielectric layer may be coated on the actuation electrodes.

The shape of each actuator is such that the gap between an actuator and its corresponding actuation electrode is largest at the end where the actuator is coupled to the mover, and is narrowest at the end where the actuator is coupled to its corresponding anchor. In this way, as a voltage is applied to an actuation electrode, the corresponding actuator moves toward the actuation electrode, and this movement is such that the actuator movers closer to the actuation electrode as the voltage increases. That is, the gap will narrow, starting at the end near the anchor, and will continue to decrease toward the other end as the actuation voltage on the actuation electrode is increased. One may visual this as a “zipper” type action, and accordingly, one may refer to the actuators as zipper actuators.

By applying various voltages to the four actuation electrodes, 202b, 204b, 206b, and 208b, the mover may be caused to move in an arbitrary lateral direction. It is expected that tethering beams may help balance any rotational torque due to the actuation electrodes, thereby helping to reduce rotation of the mover as it is moved by the actuation electrodes.

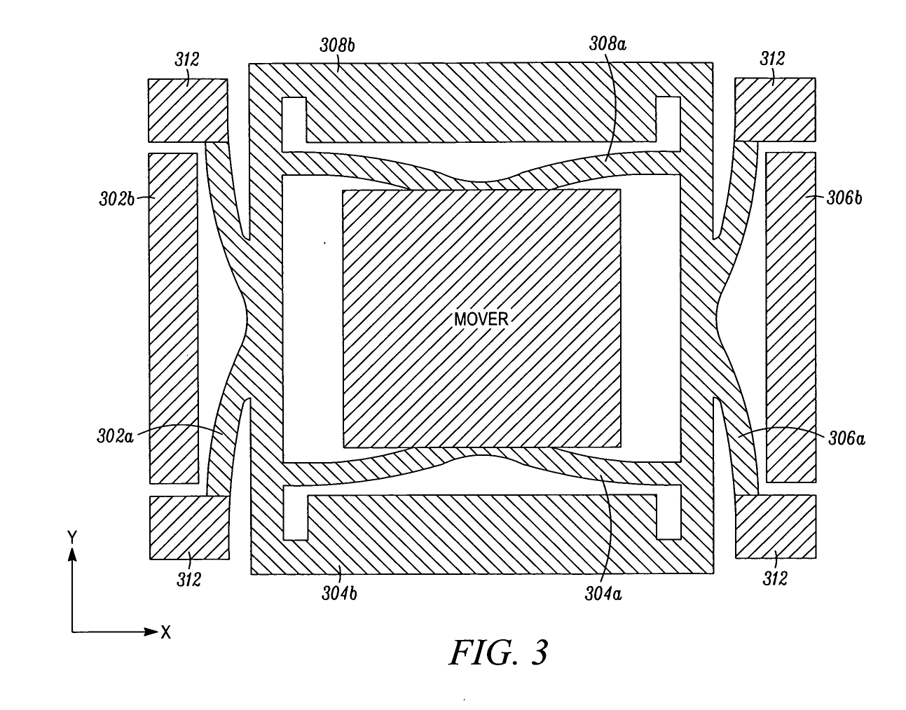

FIG. 3 illustrates another embodiment, which may also help in reducing rotation of the mover. Components in FIG. 3 are labeled in similar fashion to their corresponding components in FIG. 2, except that the first numeral in each label is a 3 instead of a 2. For the particular embodiment of FIG. 3, actuation electrodes 308b and 304b are moved, along with the mover, due to actuators 302b and 306b.

Some embodiments may use differently shaped actuators. For example, for some embodiments, the actuators may be asymmetrical, where the gap between the actuator and its corresponding actuation electrode is narrow at the end where the actuator is coupled to its corresponding anchor, and then widens toward the end of the actuator that is coupled to the mover.

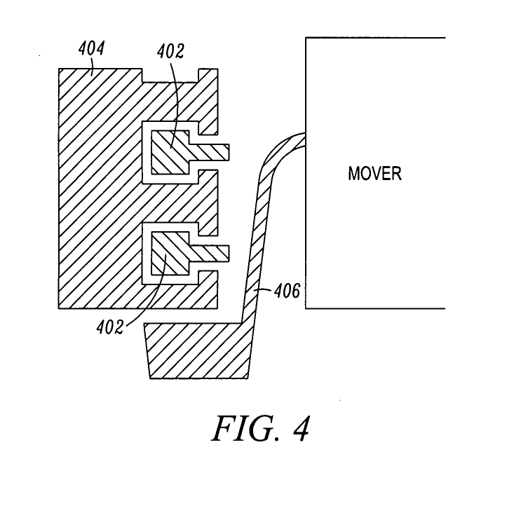

An actuation electrode and its corresponding actuator should be electrically isolated from each other to prevent actuation shorting. Dielectric coatings may be used. Other embodiments may use stoppers, such as illustrated in FIG. 4. In FIG. 4, stoppers 402 are anchored to the CMOS substrate (not shown). As actuation electrode 404 pulls actuator 406 inward, it may rest on one or more stoppers so that there isn't an actuation short. Note that the shape of the actuator in FIG. 4 is different than in the previous embodiments. As discussed above, an actuator may be asymmetrical in design, such as that illustrated in FIG. 4.

Embodiments are not limited to seek-scan-probe memory devices, but may find application to devices in which a platform is to be moved in a lateral direction. Accordingly, the term mover is to be given a broad interpretation to include platforms moveable in lateral dimension.

Various modifications may be made to the described embodiments without departing from the scope of the invention as claimed below.

What is claimed is:

1. An apparatus comprising:
an anchor;
a platform;
an actuation electrode; and
an actuator having a first region coupled to the platform and a second region coupled to the anchor such that there is a gap between the actuator and the actuation electrode, wherein the gap is decreasing from the first region to the second region.

2. The apparatus as set forth in claim 1, further comprising:
a tethering beam, wherein the actuator is coupled to the platform by way of the tethering beam.

3. The apparatus as set forth in claim 1, further comprising a dielectric coating on the actuation electrode.

4. The apparatus as set forth in claim 3, further comprising non-conductive stoppers adjacent to the actuation electrode.

5. An apparatus comprising:
a platform;
a first actuator having a first region coupled to the platform and a second region;
a first actuation electrode such that a first gap is formed between the first actuator and the first actuation electrode, wherein the first gap is decreasing from the first region of the first actuator to the second region of the first actuator;
a second actuator having a first region coupled to the platform and a second region; and
a second actuation electrode such that a second gap is formed between the second actuator and the second actuation electrode, wherein the second gap is decreasing from the first region of the second actuator to the second region of the second actuator.

6. The apparatus as set forth in claim 5, further comprising:
a second platform comprising the platform, the first and second actuators, and the first and second actuation electrodes;
a third actuator having a first region coupled to the second platform and a second region;
a third actuation electrode such that a third gap is formed between the third actuator and the third actuation electrode, wherein the third gap is decreasing from the first region of the third actuator to the second region of the third actuator;
a fourth actuator having a first region coupled to the second platform and a second region; and
a fourth actuation electrode such that a fourth gap is formed between the fourth actuator and the fourth actuation electrode, wherein the fourth gap is decreasing from the first region of the fourth actuator to the second region of the fourth actuator.

7. The apparatus as set forth in claim 5, further comprising:
a third actuator having a first region coupled to the platform and a second region;
a third actuation electrode such that a third gap is formed between the third actuator and the third actuation electrode, wherein the third gap is decreasing from the first region of the third actuator to the second region of the third actuator;
a fourth actuator having a first region coupled to the platform and a second region; and
a fourth actuation electrode such that a fourth gap is formed between the fourth actuator and the fourth actuation electrode, wherein the fourth gap is decreasing from the first region of the fourth actuator to the second region of the fourth actuator.
